(19) United States
(12) Patent Application Publication
(10) Pub. No.: US 2015/0048333 A1
(43) Pub. Date: Feb. 19, 2015

(54) ORGANIC LIGHT EMITTING DIODE DISPLAY AND METHOD FOR PREPARING THE SAME

(71) Applicant: SAMSUNG DISPLAY CO., LTD., Yongin-City (KR)

(72) Inventors: Jin Woo CHOI, Seoul (KR); Hae Yun CHOI, Hwaseong-si (KR); Min Woo KIM, Hwaseong-si (KR)

(21) Appl. No.: 14/327,610

(22) Filed: Jul. 10, 2014

(30) Foreign Application Priority Data
Aug. 13, 2013 (KR) 10-2013-0096047

(51) Int. Cl. H01L 27/32; H01L 51/52; H01L 51/56

(52) U.S. Cl. CPC H01L 27/322; H01L 51/56; H01L 51/5275
USPC 257/40; 438/29

(57) ABSTRACT

An organic light emitting diode display includes an organic light emitting panel, a high refractive organic film layer on the organic light emitting panel, the high refractive organic film layer including a convex portion having a convex shape with respect to the organic light emitting panel, a low refractive organic film layer on the high refractive organic film, the low refractive organic film layer including a concave portion corresponding to the convex portion of the high refractive organic film layer, a color filter on the low refractive organic film layer, and a light blocking member having an opening corresponding to the color filter.

### CROSS-REFERENCE TO RELATED APPLICATION

Korean Patent Application No. 10-2013-0096047, filed on Aug. 13, 2013, in the Korean Intellectual Property Office, and entitled: “Organic Light Emitting Diode Display and Method For Preparing The Same,” is incorporated by reference herein in its entirety.

### BACKGROUND

1. Field

Embodiments relate to an organic light emitting diode display and a method for preparing the same.

2. Description of the Related Art

An organic light emitting diode display is a self-light emitting display device which forms excitons by recombining electrons and holes injected into an organic material through an anode and a cathode, and generates light having a predetermined wavelength by energy from the formed excitons. Accordingly, since the organic light emitting diode display does not require a separate light source, e.g., does not require a backlight unit as a LCD, the organic light emitting diode display may exhibit low power consumption, and a wide viewing angle and a rapid response speed may be easily ensured. As a result, the organic light emitting diode display has received attention as a next-generation display device.

In the organic light emitting diode display, pixels, i.e., basic units for image expression, may be arranged in a pixel area, in which an image is actually displayed on a substrate, in a matrix form. An organic light emitting element, in which a first pixel electrode as an anode and a second pixel electrode as a cathode are sequentially formed with each organic light emitting layer expressing red R, green G, and blue B, is disposed for each pixel. In addition, in the case of an active matrix type organic light emitting diode display, a thin film transistor (TFT) connected to the organic light emitting element is formed for each pixel to independently control each of the pixels.

### SUMMARY

An exemplary embodiment provide an organic light emitting diode display, including an organic light emitting panel, a high refractive organic film layer on the organic light emitting panel, the high refractive organic film layer including a convex portion having a convex shape with respect to the organic light emitting panel, a low refractive organic film layer on the high refractive organic film, the low refractive organic film layer including a concave portion corresponding to the convex portion of the high refractive organic film layer, a color filter on the low refractive organic film layer, and a light blocking member having an opening corresponding to the color filter.

The organic light emitting panel may include a thin film transistor substrate including an organic light emitting layer, and an encapsulation layer formed on the thin film transistor substrate.

A thickness of the encapsulation layer may be 1 to 10 μm.

The high refractive organic film layer may use one or more kinds selected from a group constituted by TiOₓ, ZrOₓ and SiNₓ as a nano high refractive bead, and the low refractive organic film layer may use a fluorine based material or air nano bead particles.

A formation angle of a convex portion of the high refractive organic film layer and a concave portion of the low refractive organic film layer corresponding to the convex portion may be 10° to 80° according to a size of each pixel.

Heights of the convex portion of the organic film layer and the concave portion corresponding to the convex portion may be in a range of 1 to 6 μm.

Widths of the convex portion of the organic film layer and the concave portion corresponding to the convex portion may be −5 to +5 μm with respect to the width of each pixel according to widths of the red, green, and blue pixels.

A total thickness of the organic film layers may be 5 to 20 μm.

A refractive index of the high refractive organic film layer may have a range of 1.7 to 1.9, and a refractive index of the low refractive organic film layer may have a range of 1.2 to 1.5.

The high refractive organic film layer and the low refractive organic film layer may be configured in a mono lens form or a multi lens form.

A thickness of the light blocking member may be 1 to 5 μm.

A linear distance in formation position between the light blocking member and the organic light emitting layer may be 2 to 6 μm.

A thickness of the color filter may be 1 to 5 μm.

An adhesive layer may be additionally formed between the encapsulation layer and the organic film layer or between the organic film layer and the color filter.

A thickness of the adhesive layer may be 5 to 50 μm.

A flat portion having a flat shape may be additionally included at a center of the convex portion of the organic film layer and a concave portion corresponding to the convex portion.

The flat portion may be 50 to 70% of the entire area of each pixel.

Another exemplary embodiment provides a method for preparing an organic light emitting diode display, including: forming a light blocking member on a boundary between pixels of red, green, and blue pixels of a color filter formed on a substrate; forming a low refractive organic film layer including a concave portion having a concave pattern between the light blocking members on the color filter with the light blocking member; adhering a high refractive organic film layer including a convex portion corresponding to the concave portion on the low refractive organic film layer by using an adhesive; and bonding a thin film transistor substrate including an organic light emitting layer on the high refractive organic film layer.

The light blocking member may be formed to have a height of 1 to 5 μm.

The adhesive may use urethane acrylate resin or 2-hydroxy ethyl acrylate.

The bonding of the thin film transistor substrate may use a UV curing method.

### BRIEF DESCRIPTION OF THE DRAWINGS

Features will become apparent to those of ordinary skill in the art by describing in detail exemplary embodiments with reference to the attached drawings, in which:

FIG. 1 illustrates a diagram of a thin film encapsulation structure of a pixel having a mono lens form of an organic light emitting diode display according to an exemplary embodiment.

FIG. 2 illustrates a diagram of a thin film encapsulation structure of a pixel having a multi-lens form of the organic light emitting diode display according to the exemplary embodiment.

FIG. 3 illustrates a diagram of a progress direction of light depending on a thin film encapsulation structure of the organic light emitting diode display according to the exemplary embodiment.

FIG. 4 illustrates a diagram of a thin film encapsulation structure of an organic light emitting diode display according to another exemplary embodiment.

FIG. 5 illustrates a diagram of a thin film encapsulation structure of a pixel of an organic light emitting diode display according to yet another exemplary embodiment.

FIG. 6 illustrates a diagram of a progress direction of light depending on the thin film encapsulation structure of the organic light emitting diode display according to yet another exemplary embodiment.

FIGS. 7 to 10 illustrate stages in a method for preparing an organic light emitting diode display according to an exemplary embodiment.

FIGS. 11 to 15 illustrate diagrams of thin film encapsulation structures of organic light emitting diode displays according to exemplary embodiments in which a position of a light blocking member is opposite to that of the light blocking member in the structure of FIGS. 1 to 5.

FIG. 16 illustrates an equivalent circuit diagram of an organic light emitting diode display according to an exemplary embodiment.

FIG. 17 illustrates a layout view of an organic light emitting diode display according to an exemplary embodiment.

FIG. 18 illustrates a cross-sectional view taken along line of FIG. 16.

FIG. 19 illustrates a cross-sectional view taken along line IV-IV of FIG. 16.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey exemplary implementations to those skilled in the art.

In the drawings, the thickness of layers, films, panels, regions, etc., may be exaggerated for clarity. Like reference numerals designate like elements throughout the specification. It will be understood that when an element such as a layer, film, region, or substrate is referred to as being “on” another element, it can be “directly on” the other element or intervening elements may also be present. In contrast, when an element is referred to as being “directly on” another element, there are no intervening elements present.

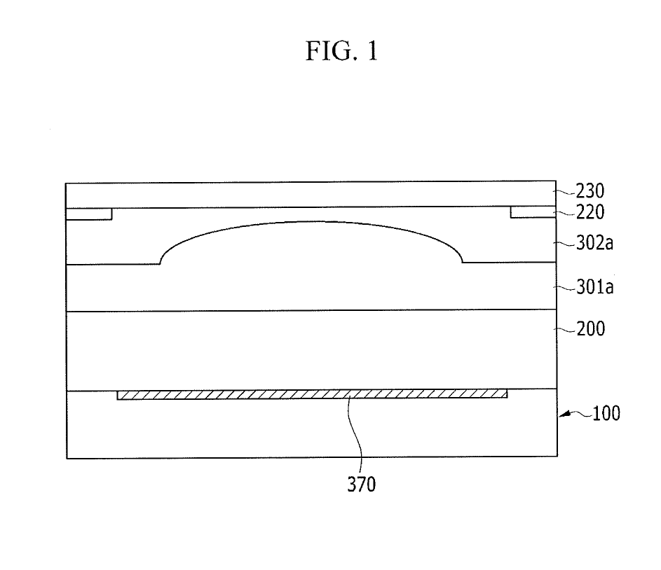

Hereinafter, an organic light emitting diode display and a method for preparing the same according to an exemplary embodiment will be described in detail with reference to the drawings. Then, a thin film encapsulation structure of the organic light emitting diode display according to the exemplary embodiment will be described in detail with reference to FIGS. 1 to 3.

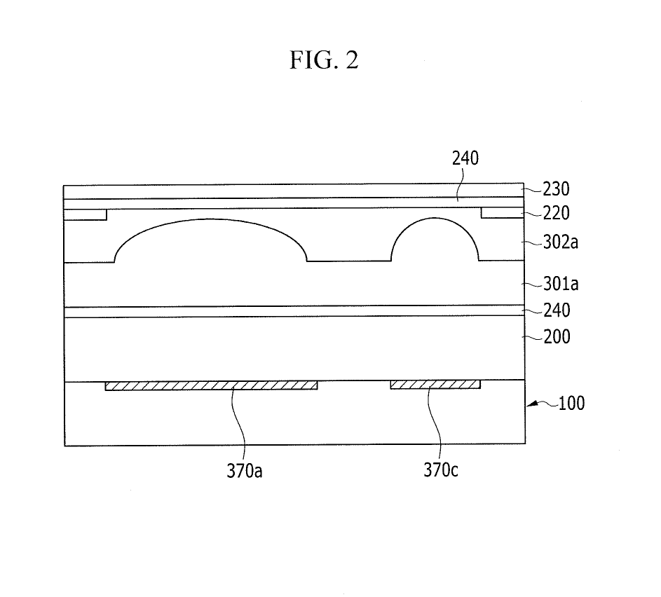

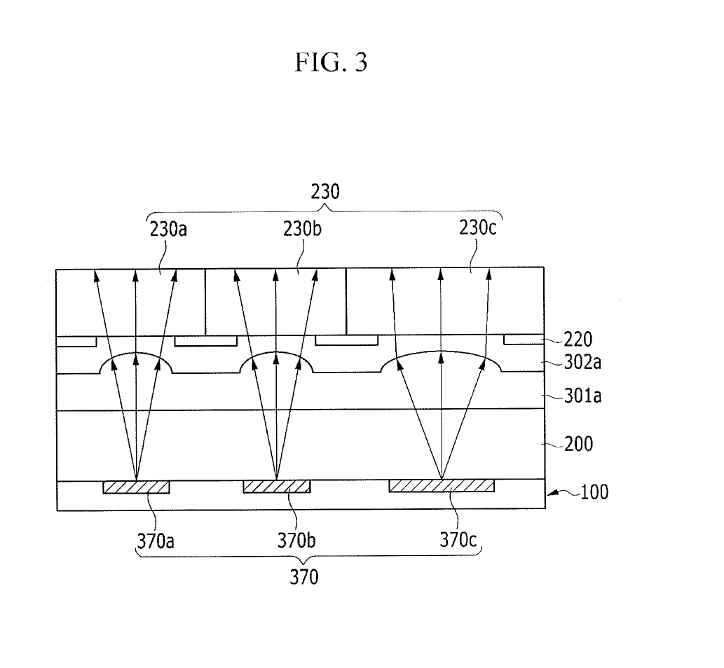

FIG. 1 illustrates a diagram of a thin film encapsulation structure of one pixel having a mono lens form of an organic light emitting diode display according to an exemplary embodiment, FIG. 2 illustrates a diagram of a thin film encapsulation structure of one pixel having a multi-lens form, and FIG. 3 illustrates a diagram illustrating a progress direction of light depending on a thin film encapsulation structure.

As illustrated in FIG. 1, a thin film encapsulation structure of an organic light emitting diode display according to an exemplary embodiment may include an organic light emitting panel, a thin lens structure on the organic light emitting panel, and a color filter on the lens structure. In detail, the organic light emitting panel may include a thin film transistor substrate 100 with an organic light emitting layer 370, and an encapsulation layer 200 on the thin film transistor substrate 100. The thin lens structure may include a high refractive organic film layer 301 a and a low refractive organic film layer 302a on the encapsulation layer 200. A light blocking member 220 and a color filter 230 may be on the low refractive organic film layer 302a.

In further detail, the encapsulation layer 200 formed on the thin film transistor substrate 100 including the organic light emitting layer 370, the high refractive organic film layer 301a formed on the encapsulation layer 200, the low refractive organic film layer 302a formed on the high refractive organic film layer 301a, the light blocking member 220 formed between respective pixels of red R, green G, and blue B on the low refractive organic film layer 302a, and the color filter 230 formed on the low refractive organic film layer 302a and the light blocking member 220 may be configured, e.g., sequentially laminated on the thin film transistor substrate 100. The high refractive organic film layer 301a and low refractive organic film layer 302a have convex and concave shapes, respectively, that are oriented toward the color filter 230 according to a size of each pixel, as will be described in more detail below.

The encapsulation layer 200 for sealing the organic light emitting layer 370 on the thin film transistor substrate 100 may be made of glass or metal. The encapsulation layer 200 is coated with a sealant along an outermost circumference direction, and then a lower side of the encapsulation layer 200 contacts the thin film transistor substrate 100. The sealant may be used as various materials, e.g., inorganic or organic sealants.

A thickness of the encapsulation layer 200 may be about 1 μm to about 10 μm. When the thickness of the encapsulation layer 200 is smaller than about 1 μm, moisture and the like may easily flow into the organic light emitting layer 370 from the outside. When the thickness of the encapsulation layer 200 is larger than about 10 μm, an angle at which light generated from the organic light emitting layer 370 and passes through the color filter 230 to be dispersed may be decreased, thereby reducing the viewing angle and the light emitting efficiency.

The high refractive organic film layer 301a and the low refractive organic film layer 302a may be sequentially formed on, e.g., directly on, the encapsulation layer 200 to improve light efficiency of light generated from the organic light emitting layer 370. For example, as illustrated in FIG. 1, the high refractive organic film layer 301a may be, e.g., directly, between the low refractive organic film layer 302a and the encapsulation layer 200. The high refractive organic film layer 301a may include, e.g., TiOₓ, ZrOₓ and/or SiN_{X} as nano high refractive beads, and the low refractive organic film layer 302a may include, e.g., a fluorine based material or air nano bead particles, but they are not limited thereto.

The high refractive organic film layer 301a includes a flat portion on the encapsulation layer 200 and a convex portion on the flat portion. The convex portion is formed in a convex lens shape toward the color filter 230, e.g., the convex portion may be a curved portion protruding from the flat portion toward the color filter 230. The convex portion of the high refractive organic film layer 301a may be positioned between the light blocking members 220 among respective pixels, e.g., the convex portion may be centered between two adjacent light blocking members 220.

The low refractive organic film layer 302a includes a concave portion corresponding to the convex portion of the high refractive organic film layer 301a. For example, as illustrated in FIG. 1, the concave portion of the low refractive organic film layer 302a may face and completely overlap, e.g., may be complementary with respect to, the convex portion of the high refractive organic film layer 301a. The concave portion of the low refractive organic film layer 302a may be formed toward the color filter 230 between the light blocking members 220 formed on a boundary of each pixel.

Initial formation angles of the convex portion of the high refractive organic film layer 301a and the concave portion of the low refractive organic film layer 302a corresponding thereto may have formation angles of about 10 degrees to about 80 degrees relative to a corresponding flat portion of the low or high refractive organic film layer and according to a size of each pixel. Heights of the convex portion of the high refractive organic film layer 301a and the concave portion of the low refractive organic film layer 302a corresponding thereto may be about 1 μm to about 6 μm, and widths of the convex portion and the concave portion may be about (−5) μm to about (+5) μm of a width of each pixel according to a size of each pixel.

A total, e.g., combined, thickness of the high refractive organic film layer 301a and the low refractive organic film layer 302a may be about 20 μm or less, e.g., about 5 μm to about 20 μm. As the thicknesses of the organic film layers 301a and 302a are decreased, a distance at which light of the organic light emitting layer 370 is transmitted is decreased, and a region of light progressing toward the light blocking member 220 is reduced. As a result, light efficiency of the organic light emitting diode display may be further improved.

A refractive index of the high refractive organic film layer 301a may have a range of about 1.7 to about 1.9. A refractive index of the low refractive organic film layer 302a may have a range of about 1.2 to about 1.5.

For example, the high refractive organic film layer 301a and the low refractive organic film layer 302a may be configured in a mono lens form, i.e., a structure having a single convex portion and a single concave portion corresponding thereto formed in one pixel, as illustrated in FIG. 1. In another example, the high refractive organic film layer 301a and the low refractive organic film layer 302a may be configured in a multi lens form, i.e., a structure having a plurality of convex portions adjacent to each other along a horizontal direction and a plurality of concave portions corresponding thereto in one pixel, as illustrated in FIG. 2. For example, as illustrated in FIG. 2, each of the plurality of convex portions (and corresponding concave portion) overlaps a corresponding organic light emitting layer, e.g., corresponding organic light emitting layers 370a and 370c.

The organic light emitting diode display according to exemplary embodiments includes the high refractive organic film layer 301a and the low refractive organic film layer 302a. As a result, a polarizer which is generally used in a conventional organic light emitting diode display may be eliminated.

The light blocking member 220, i.e., a black matrix 220, may be positioned on the high refractive organic film layer 301a and the low refractive organic film layer 302a. The light blocking member 220 is positioned to correspond to the organic light emitting layer 370, e.g., the light blocking member 220 and the organic light emitting layer 370 have a non-overlapping relationship.

A thickness of the light blocking member 220 may be about 1 μm to about 5 μm. When the thickness of the light blocking member 220 is smaller than 1 μm, the light blocking member 220 may insufficiently block light, thereby causing light leakage. When the thickness of the light blocking member 220 is larger than 5 μm, an angle at which light generated from the organic light emitting layer 370 passes through the color filter 230 to be dispersed may be decreased, thereby decreasing the viewing angle.

A linear distance of a formation position between the light blocking member 220 and the organic light emitting layer 370 is about 2 μm to about 6 μm, in consideration of a formation error.

The color filter 230 may be formed on the light blocking member 220 and the low refractive organic film layer 302a, and a thickness of the color filter 230 may be about 1 μm to about 5 μm. When the thickness of the color filter 230 is smaller than 1 μm, color purity is deteriorated and it is difficult to implement an accurate color. When the thickness of the color filter 230 is larger than 5 μm, light emission efficiency is deteriorated and the viewing angle may be reduced. The thickness of the color filter 230 may be the same as the thickness of the light blocking member 220. A width of the color filter 230 may be larger than a width of the organic light emitting layer 370, so light emitted from the organic light emitting layer 370 may be more widely dispersed in the color filter 230 to improve the viewing angle.

Further, an adhesive layer (not illustrated) may be additionally formed between the encapsulation layer 200 and the high and low refractive organic film layers 301a and 302a, or between the high and low refractive organic film layers 301a and 302a and the color filter 230. The adhesive layer may be made of a transparent material, and may have a thickness of about 5 μm to about 50 μm. When the adhesive layer has a thickness smaller than 5 μm, the adhesion between the layers may be deteriorated. When the adhesive layer has a thickness larger than 50 μm, an angle at which the light generated from the organic light emitting layer 370 passes through the color filter 230 to be dispersed is decreased and thus the viewing angle may be reduced.

Referring to FIG. 3, an organic light emitting diode display may include a plurality of pixels having the structure illustrated in FIG. 1. As such, the organic light emitting diode display may include pixels of a red pixel 230a, a green pixel 230b, and a blue pixel 230c.

Light emitted from each organic light emitting layer 370 of a red organic light emitting layer 370a, a green organic light emitting layer 370b, and a blue organic light emitting layer 370c passes through the encapsulation layer 200, and light scattered by passing through the convex portion of the high refractive organic film layer 301a and the concave portion of the low refractive organic film layer 302a corresponding thereto is concentrated at a center of the pixel by the convex portion and the concave portion corresponding thereto to be dispersed through each color filter 230 of the red pixel 230a, the green pixel 230b, and the blue pixel 230c between the light blocking members 220. The light emitted and scattered from the organic light emitting layer 370 is concentrated by the convex portion and the concave portion corresponding thereto to be emitted through the color filter 230 while light blocked by the light blocking member 220 is minimized.

Further, as the thicknesses of the high refractive organic film layer 301a and the low refractive organic film layer 302a are increased, a moving distance, e.g., a path, of the light through the high refractive organic film layer 301a and the low refractive organic film layer 302a is increased. Thus, a region where the light is emitted is further increased, e.g., an area through which light is emitted out of the low refractive organic film layer 302a toward the color filter 230 may increase to overlap the light blocking member 220. As a result, to avoid decreased light efficiency of the organic light emitting diode display, e.g., light loss due to overlap with the light blocking member 220, a combined thickness of the high refractive organic film layer 301a and the low refractive organic film layer 302a may be 20 μm or less.

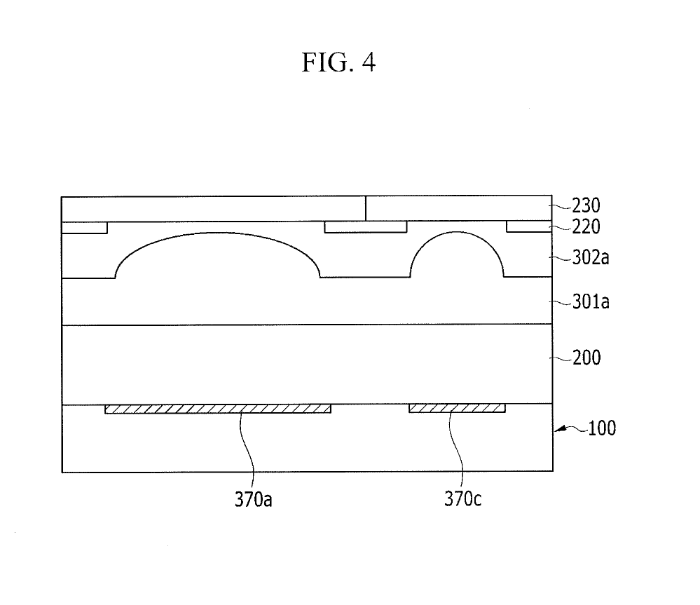

Next, a thin film encapsulation structure of an organic light emitting diode display according to another exemplary embodiment will be described in detail with reference to FIG. 4. FIG. 4 illustrates a diagram of a thin film encapsulation structure of an organic light emitting diode display according to another exemplary embodiment.

Referring to FIG. 4, a thin film encapsulation structure of an organic light emitting diode display may include a plurality of pixels having different widths. For example, as illustrated in FIG. 4, the red pixel 230a and the blue pixel 230c may have widths different from each other.

In detail, when the widths of the pixels 230a and 230c are increased, widths of the organic light emitting layers 370a and 370c corresponding to the respective pixels 230a and 230c are increased. As a result, in order to increase efficiency of light emitted and scattered from the organic light emitting layers 370a and 370c, widths of the convex portion of the high refractive organic film layer 301a and the concave portion of the low refractive organic film layer 302a are increased respectively.

Then, referring to FIG. 4, as the width of the pixel is increased, the widths of the convex portion and the concave portion corresponding thereto are increased. In order for the widths of the convex portion and the concave portion corresponding thereto to increase, an initial angle of the convex portion and the concave portion corresponding thereto is adjusted to be smaller, e.g., compared to convex and concave portions in pixels having a smaller width. Similarly, as the width of the pixel is decreased, the initial angle of the convex portion and the concave portion corresponding thereto is increased relatively to convex and concave portions in a pixel having a larger width.

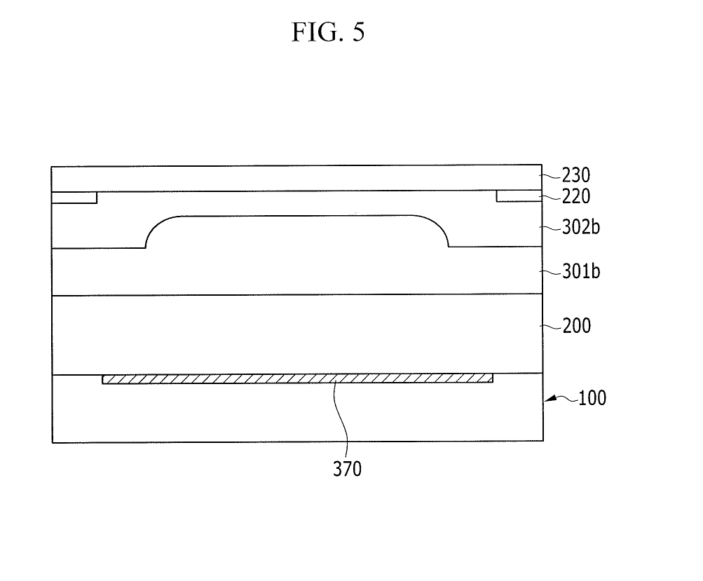

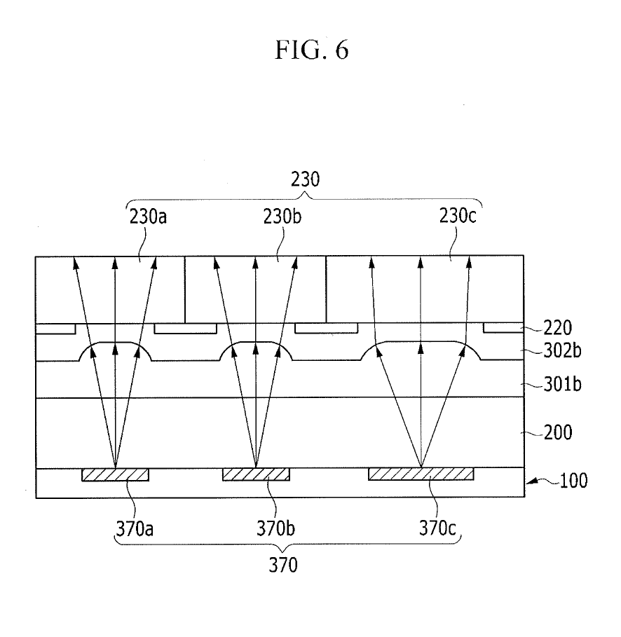

Next, a thin film encapsulation structure of one pixel of an organic light emitting diode display according to yet another exemplary embodiment will be described with reference to FIGS. 5 and 6. FIG. 5 illustrates a diagram of a thin film encapsulation structure of one pixel of an organic light emitting diode display according to yet another exemplary embodiment, and FIG. 6 illustrates a diagram illustrating a progress direction of light depending on the thin film encapsulation structure of the organic light emitting diode display.

As illustrated in FIG. 5, in a thin film encapsulation structure of an organic light emitting diode display according to yet another exemplary embodiment, a thin film transistor substrate 100 including the organic light emitting layer 370, the encapsulation layer 200, a high refractive organic film layer 301b, a low refractive organic film layer 302b, a light blocking member 220, and a color filter 230 are sequentially laminated. In detail, the encapsulation layer 200 formed on the thin film transistor substrate 100 including the organic light emitting layer 370, the high refractive organic film layer 301b formed on the encapsulation layer 200, the low refractive organic film layer 302b formed on the high refractive organic film layer 301b, the light blocking member 220 formed between respective pixels of red R, green G, and blue B on the low refractive organic film layer 302a, and the color filter 230 formed on the low refractive organic film layer 302b and the light blocking member 220 are configured.

In addition, the high refractive organic film layer 301b includes a convex portion which is convex toward the color filter 230 according to a size of each pixel, and the low refractive organic film layer 302b includes a concave portion corresponding to the convex portion. As illustrated in FIG. 5, centers of the convex portion and the concave portion corresponding thereto have flat shapes, e.g., as compared to the exemplary embodiment of FIG. 1. That is, since strong light is emitted from a center of an optical distribution by the organic light emitting layer 370 of the organic light emitting diode display, the centers of the convex portion and the concave portion corresponding thereto of the organic film layers 301b and 302b have flat shapes in order to maximize light emission from the center of the organic light emitting layer 370 and minimize light loss.

An area of the flat shape of the convex portion and the concave portion corresponding thereto of the organic film layers 301b and 302b may be formed by about 50 to 70% of the entire area of the pixel. For example, a flat interface area between the organic film layers 301b and 302b may be about 50% to about 70% of a top surface of the color filter 230.

The high refractive organic film layer 301b and the low refractive organic film layer 302b improve light efficiency of light generated from the organic light emitting layer 370. The high refractive organic film layer 301b may include, e.g., TiOₓ, ZrOₓ and SiNₓ as a nano high refractive bead, and the low refractive organic film layer 302b may include, e.g., fluorine based material or air nano bead particles, but they are not limited thereto.

Initial formation angles of the convex portion of the high refractive organic film layer 301b and the concave portion of the low refractive organic film layer 302b corresponding thereto may have formation angles of about 10 degrees to about 80 degrees according to a size of each pixel. Heights of the convex portion of the high refractive organic film layer 301b and the concave portion of the low refractive organic film layer 302b corresponding thereto may be about 1 μm to about 6 μm, and widths of the convex portion and the concave portion may be about (−5) to about (+5) μm of a width of each pixel according to a size of each pixel.

The combined thickness of the high refractive organic film layer 301b and the low refractive organic film layer 302b may be about 20 μm or less. That is, as the thicknesses of the organic film layers 301b and 302b are decreased, a distance at which light of the organic light emitting layer 370 is transmitted is decreased, and a region of light progressing toward the light blocking member 220 is reduced. As a result, light efficiency of the organic light emitting diode display may be further improved.

A refractive index of the high refractive organic film layer 301b may have a range of about 1.7 to about 1.9, and a refractive index of the low refractive organic film layer 302b may have a range of about 1.2 to about 1.5.

The high refractive organic film layer 301b and the low refractive organic film layer 302b may be configured in a mono lens form, in which a pair of a convex portion and a concave portion corresponding thereto of the organic film layers 301b and 302b is formed in one pixel, or in a multi lens form in which a plurality of convex portions and concave portions corresponding thereto of the organic film layers 301b and 302b is formed in one pixel.

A structure of other layers other than the organic film layers 301b and 302b of FIG. 6 may be applied in the same way as illustrated in FIG. 1. Referring to FIG. 6, it is noted that a plurality of pixels having the structure illustrated in FIG. 5 may be combined to provide an organic light emitting diode display having pixels of the red pixel 230a, the green pixel 230b, and the blue pixel 230c.

Light emitted from each organic light emitting layer 370 of the red organic light emitting layer 370a, the green organic light emitting layer 370b, and the blue organic light emitting layer 370c passes through the encapsulation layer 200, passes through the flat portion of a center formed at the center of the convex portion of the high refractive organic film layer 301b and the concave portion of the low refractive organic film layer 302b corresponding thereto, and the light scattered to both sides is concentrated at edges of the convex portion and the concave portion corresponding thereto and passes through the flat portion to be emitted through each color filter 230 of the red pixel 230a, the green pixel 230b, and the blue pixel 230c between the light blocking members 220. While the light emitted and scattered from the organic light emitting layer 370 is concentrated by the convex portion and the concave portion corresponding thereto of the organic film layers 301b and 302b, the light blocked by the light blocking member 220 is minimized to be emitted through the color filer 230. The strongest light emitted from the center of the organic light emitting layer 370 is emitted from the flat portion of the center of the organic film layers 301b and 302b without a loss, thereby further improving light efficiency.

As the thicknesses of the high refractive organic film layer 301b and the low refractive organic film layer 302b are increased, a moving distance of the light is increased and thus a region where the light is emitted is further increased. As a result, to avoid decrease in light efficiency of the organic light emitting diode display, the thicknesses of the high refractive organic film layer 301b and the low refractive organic film layer 302b may be about 20 μm or less.

When the widths of the respective pixels 230a, 230b, and 230c are increased, the widths of the organic light emitting layers 370a, 370b, and 370c corresponding to the respective pixels 230a, 230b, and 230c are increased. As a result, in order to increase efficiency of light emitted and scattered from the respective organic light emitting layers 370a, 370b, and 370c, widths of the convex portion of the high refractive organic film layer 301b, the concave portion of the low refractive organic film layer 302b corresponding thereto, and a flat-shaped portion of the convex portion and the concave portion corresponding thereto are increased together.

As the width of the pixel is increased, the widths of the convex portion, the concave portion corresponding to the convex portion, and the flat portion positioned at the center of the convex portion and the concave portion are increased. In detail, in order to increase the widths of the convex portion, the concave portion corresponding thereto, and the flat portion in the convex portion, the initial angle of the convex portion and the concave portion corresponding thereto is adjusted to be smaller than that of the convex portion and the concave portion in a pixel having a small width. Similarly, as the width of the pixel is decreased, the initial angle of the convex portion and the concave portion corresponding thereto is adjusted to be larger than that of the convex portion and the concave portion in a pixel having a large width.

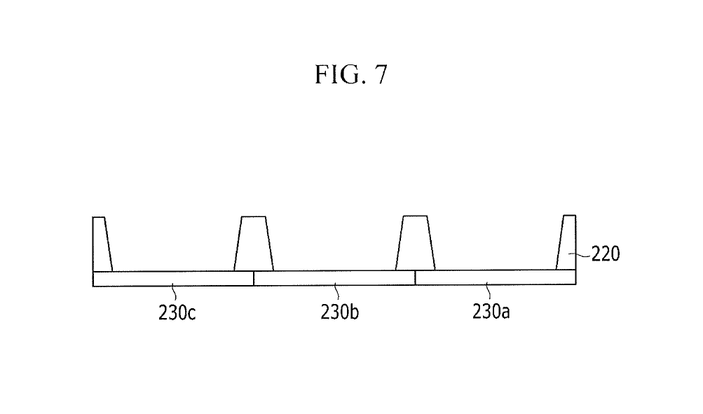

Next, a method for preparing an organic light emitting diode display according to an exemplary embodiment will be described in detail with reference to FIGS. 7 to 10.

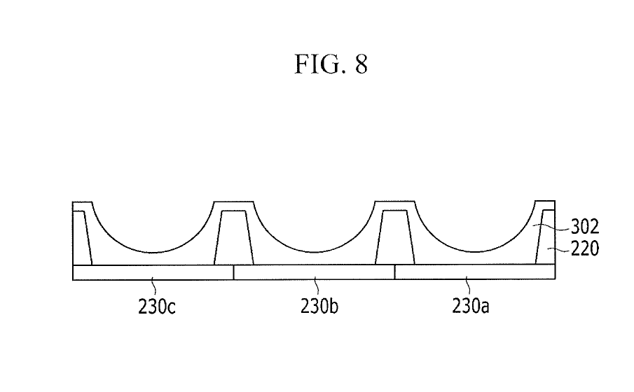

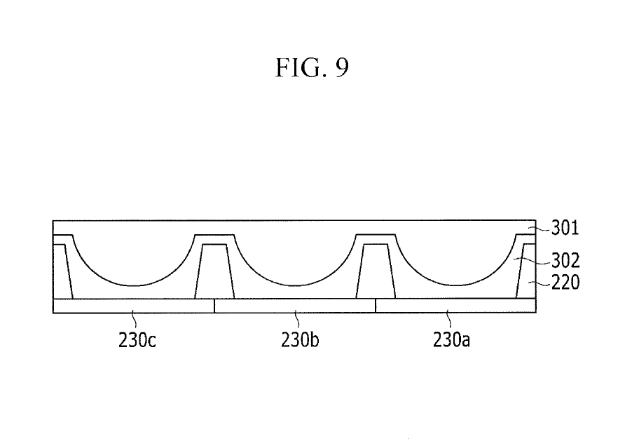

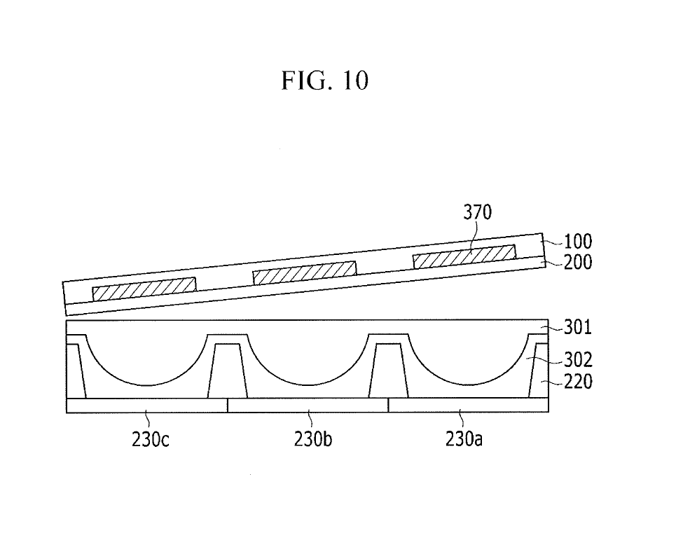

FIG. 7 illustrates a process at which the light blocking member 220 is patterned on the color filter 230 in the organic light emitting diode display according to the exemplary embodiment, FIG. 8 illustrates a process of bonding a low refractive organic film layer 302 on the light blocking member 220, FIG. 9 illustrates a process of bonding a high refractive organic film layer 301 on the light blocking member 220, and FIG. 10 illustrates a process of forming the thin film transistor substrate 100 including the organic light emitting layer 370 on the high refractive organic film layer 301.

First, referring to FIG. 7, as the process of forming the light blocking member 220 on the color filter 230 of the organic light emitting diode display, the light blocking member 220 pattern is formed at every boundary between adjacent ones of the respective pixels of the red pixel 230a, the green pixel 230b, and the blue pixel 230c of the color filter 230. A height of the light blocking member 220 is patterned to be about 1 to 5 μm.

The light blocking member 220 may also include an organic film partition additionally laminated therebelow. This is to ensure a sufficient height of the light blocking member 220 because the light blocking member 220 serves as a mold when preparing the low refractive organic film layer 302.

Next, referring to FIG. 8, as a process of forming the low refractive organic film layer 302 on the color filter 230, in which the light blocking member 220 of the organic light emitting diode display is patterned, a concave pattern is formed by coating a curable resin on the color filter 230, in which the light blocking member 220 is patterned, to form the low refractive organic film layer 302 including a concave portion having the concave pattern between the light blocking members on the color filter 230. When forming the low refractive organic film layer 302, the low refractive organic film layer 302 including the concave portion having the concave pattern between the light blocking members is formed by using a leveling characteristic due to the light blocking member 220 formed on the color filter 230.

Next, referring to FIG. 9, as a process of forming the high refractive organic film layer 301 on the low refractive organic film layer 302 formed in FIG. 8, the high refractive organic film layer 301 including a convex portion corresponding to the concave portion of the low refractive organic film layer 302 adheres onto the low refractive organic film layer 302 by using an adhesive. Then, in the high refractive organic film layer 301, the convex portion corresponding to the concave portion of the concave pattern formed in the low refractive organic film layer 302 described above may be formed. The adhesive may be, e.g., a urethane acrylate resin, or 2-hydroxy ethyl acrylate.

Next, referring to FIG. 10, as a process of bonding the thin film transistor substrate 100 including the organic light emitting layer 370 on the high refractive organic film layer 301 formed in FIG. 9, the thin film transistor substrate 100 is bonded on the high refractive organic film layer 301. Then, the organic light emitting diode display is completed by using a UV curing method.

According to the preparing method of the exemplary embodiment, since the light blocking member 220 serves as the mold, and thus a photo process needs to be performed on the encapsulation layer 200, deterioration of light efficiency and/or damage to the encapsulation layer 200 due to crystallization of the organic light emitting layer 370 may be prevented.

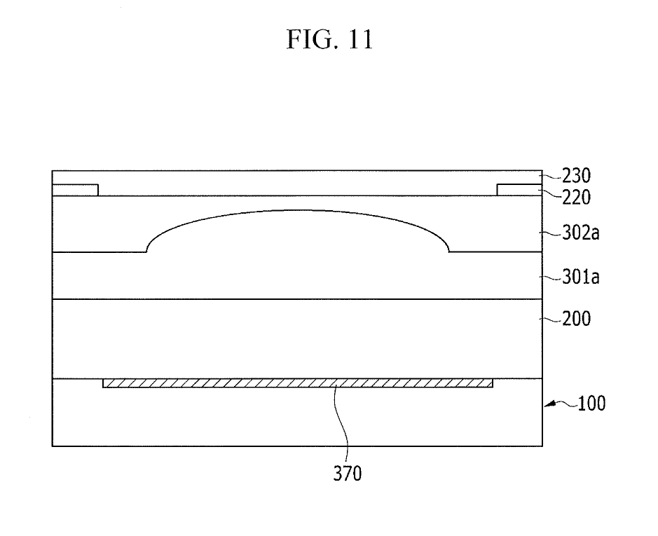

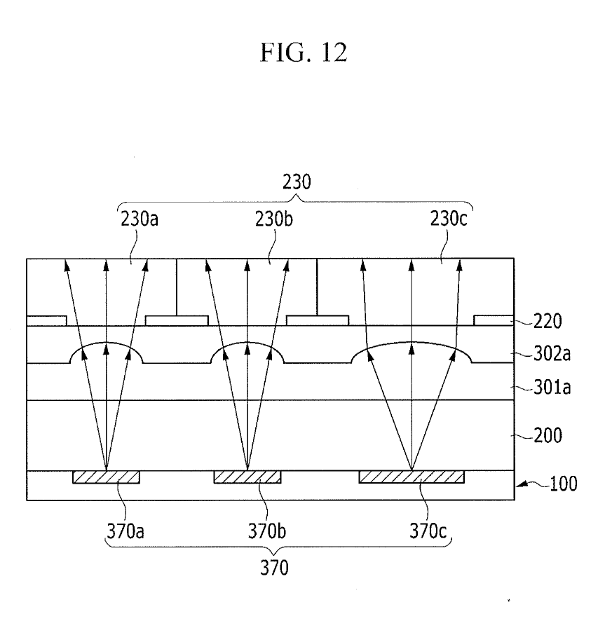

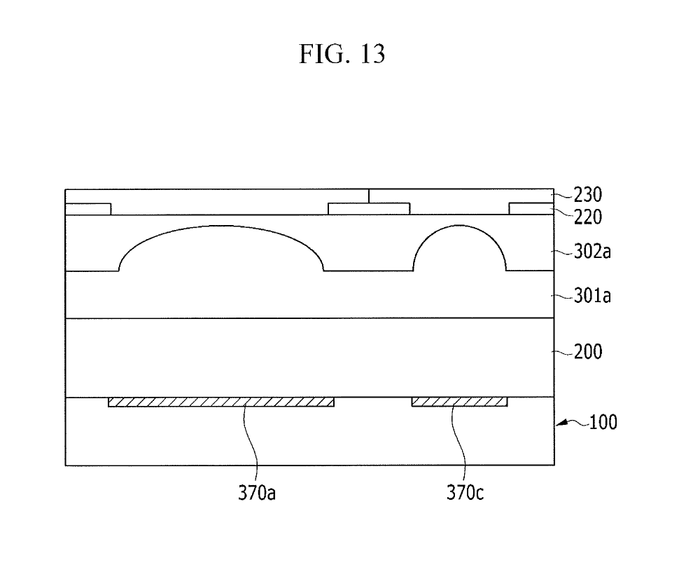

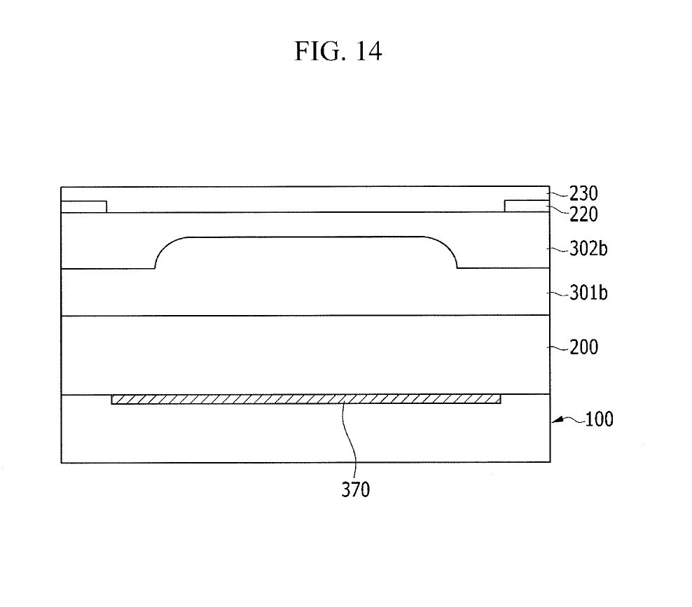

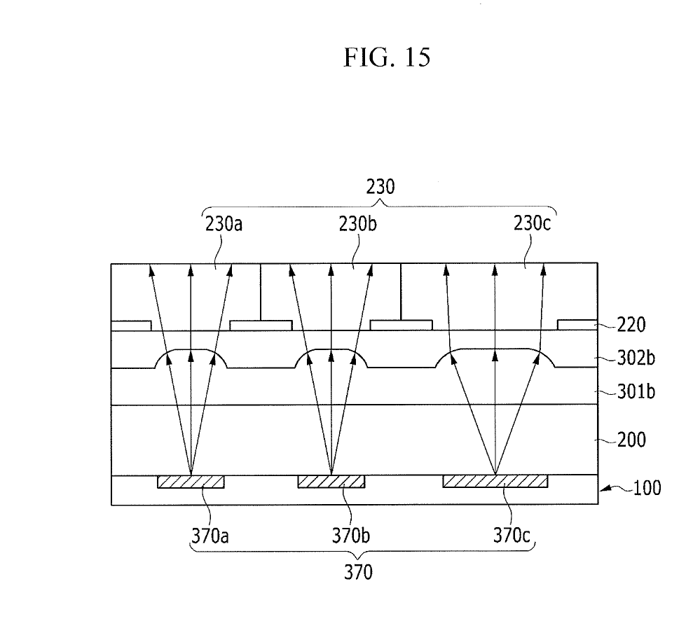

In yet another exemplary embodiment, as illustrated in FIGS. 11 to 15, the light blocking member 220 may be formed toward the color filter 230 other than the organic film layers 301 and 302. That is, the light blocking member 220 may protrude above an upper surface of the low refractive organic film layer 302a. Further, other configurations, i.e., configurations discussed previously in reference to FIGS. 1 to 5, may be applied to the embodiment in FIGS. 11-15.

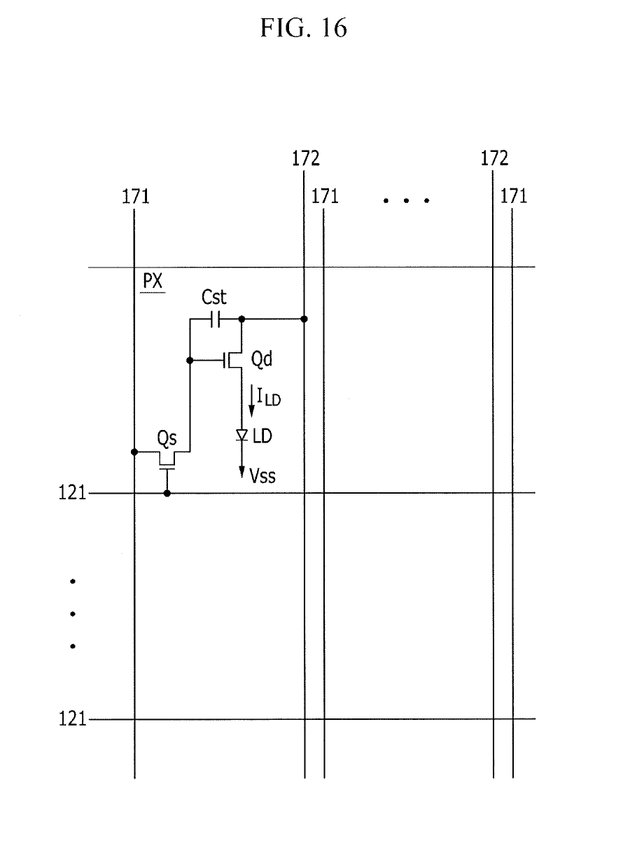

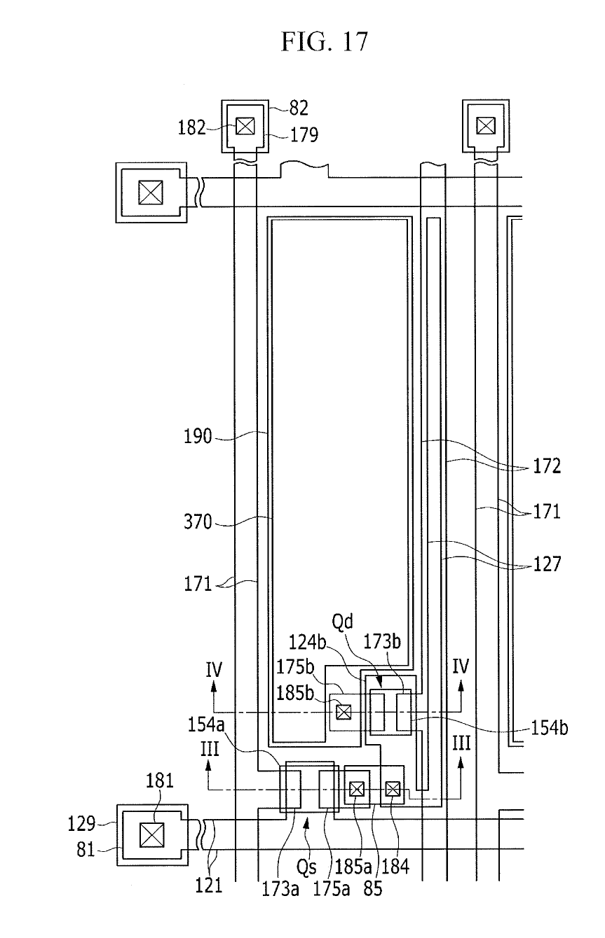

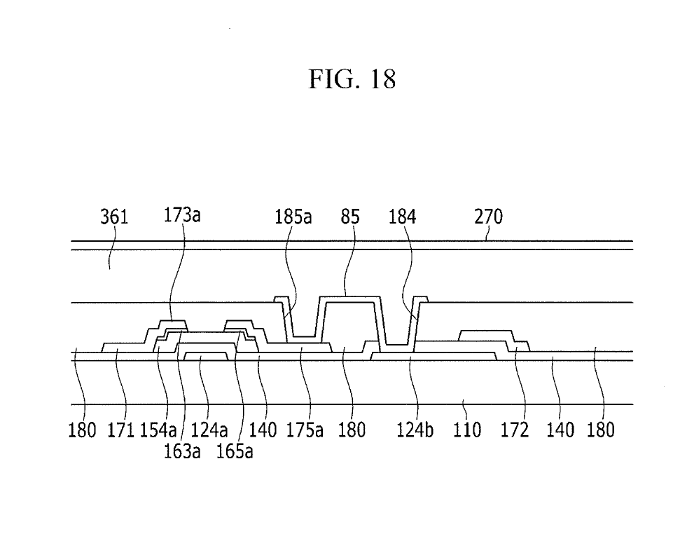

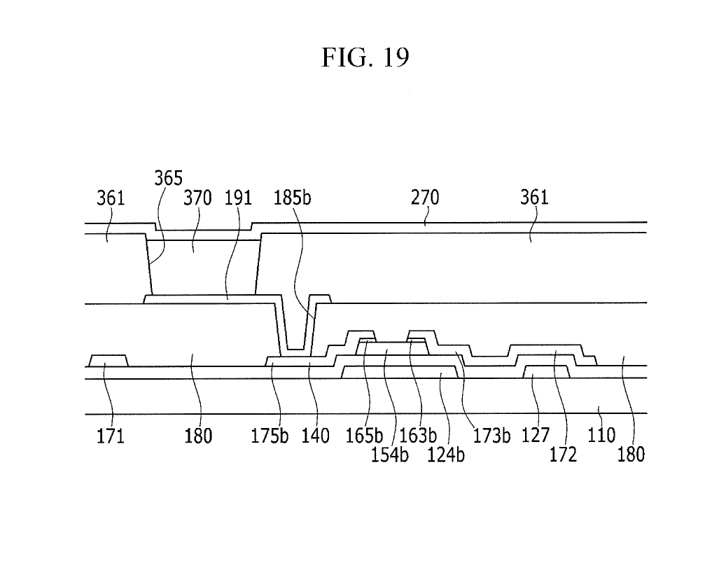

Next, the structure of the organic light emitting diode display according to embodiments will be described below with reference to FIGS. 16-19. FIG. 16 illustrates an equivalent circuit diagram of the organic light emitting diode display according to the exemplary embodiment, FIG. 17 illustrates a layout view of the organic light emitting diode display according to an exemplary embodiment, and FIGS. 18 and 19 illustrate cross-sectional views of the organic light emitting diode display of FIG. 17 taken along lines III-III and IV-IV.

Referring to FIG. 16, the organic light emitting diode display according to the exemplary embodiment includes a plurality of signal lines 121, 171, and 172, and a plurality of pixels PX connected thereto and arranged substantially in a matrix form.

The signal lines include a plurality of gate lines 121 transferring gate signals (or scanning signal), a plurality of data lines 171 transferring data signals, and a plurality of driving voltage lines 172 transferring driving voltages. The gate lines 121 extend substantially in a row direction and are substantially parallel to each other, and the data lines 171 and the driving voltage lines 172 extend substantially in a column direction and are substantially parallel to each other. Each pixel PX includes a switching transistor Qs, a driving transistor Qd, a storage capacitor Cst, and an organic light emitting diode (OLED) LD.

The switching transistor Qs has a control terminal, an input terminal, and an output terminal, and the control terminal is connected to the gate line 121, the input terminal is connected to the data line 171, and the output terminal is connected to the driving transistor Qd. The switching transistor Qs transfers a data signal applied to the data line 171 to the driving transistor Qd in response to a scanning signal applied to the gate line 121.

The driving transistor Qd also has a control terminal, an input terminal, and an output terminal, and the control terminal is connected to the switching transistor Qs, the input terminal is connected to the driving voltage line 172, and the output terminal is connected to the organic light emitting diode LD. The driving transistor Qd allows an output current I_{LD}, of which a size varies according to a voltage applied between the control terminal and the output terminal, to flow.

The capacitor Cst is connected between the control terminal and the input terminal of the driving transistor Qd. The capacitor Cst charges a data signal applied to the control terminal of the driving transistor Qd and maintains the charged data signal even after the switching transistor Qs is turned off.

The organic light emitting diode LD has an anode connected to the output terminal of the driving transistor Qd and a cathode connected to a common voltage Vss. The organic light emitting diode LD emits light by varying an intensity according to the output current I_{LD} of the driving transistor Qd to thereby display an image.

The switching transistor Qs and the driving transistor Qd are n-channel field effect transistors (FETs). However, at least one of the switching transistor Qs and the driving transistor Qd may be a p-channel field effect transistor. Further, a connection relationship of the transistors Qs and Qd, the storage capacitor Cst, and the organic light emitting diode LD may be changed.

Referring to FIGS. 17-19, a plurality of gate conductors including the plurality of gate lines 121, including a first control electrode 124a and a plurality of second control electrodes 124b, is formed on an insulation substrate 110 made of transparent glass or plastic.

The gate lines 121 transfer gate signals and extend mainly in a horizontal direction. Each gate line 121 includes a wide end portion 129 for connection with another layer or an external driving circuit, and the first control electrode 124a extends upward from the gate line 121. When a gate driving circuit (not illustrated) generating a gate signal is integrated on the substrate 110, the gate line 121 is extended to be directly connected to the gate driving circuit.

The second control electrode 124b includes a storage electrode 127 which is separated from the gate line 121 and extends downwards, turns to the right for a moment, and then elongates upwards.

The gate conductors 121 and 124b may be made of aluminum-based metal such as aluminum (Al) or an aluminum alloy, silver-based metal such as silver (Ag) or a silver alloy, copper-based metal such as copper (Cu) or a copper alloy, molybdenum-based metal such as molybdenum (Mo) or a molybdenum alloy, chromium (Cr), tantalum (Ta), and titanium (Ti), and the like. However, the gate conductors 121 and 124b may have a multilayered structure including two conductive layers (not illustrated) having different physical properties. One conductive layer thereof is made of metal having low resistivity, for example, aluminum-based metal, silver-based metal, copper-based metal, and the like, so as to reduce signal delay or voltage drop. Unlike this, the other conductive layer is made of other materials, particularly, materials having excellent physical, chemical, electrical contact characteristics such as indium tin oxide (ITO) and indium zinc oxide (IZO), for example, molybdenum-based metal, chromium, tantalum, and titanium. A proper example of such a combination may include a chromium lower layer and an aluminum (alloy) upper layer, and an aluminum (alloy) lower layer and a molybdenum (alloy) upper layer. However, the gate conductors 121 and 124b may be made of various metals or conductors in addition to the metals.

Sides of the gate conductors 121 and 124b are tilted to the surface of the substrate 110, and tilt angles thereof may be about 30° to about 80°.

A gate insulating layer 140 made of silicon nitride (SiNₓ) or silicon oxide (SiOₓ) is formed on the gate conductors 121 and 124b.

A plurality of first and second semiconductor islands 154a and 154b made of hydrogenated amorphous silicon (herein, amorphous silicon is written as an acronym a-Si) or polysilicon is formed on the gate insulating layer 140. The first and second semiconductors 154a and 154b are positioned on the first and second control electrodes 124a and 124b, respectively.

A plurality of pairs of first ohmic contacts 163a and 165a and a plurality of pairs of second ohmic contacts 163b and 165b are formed on the first and second semiconductors 154a and 154b, respectively. The ohmic contacts 163a, 163b, 165a, and 165b may have island shapes, and be made of a material such as n+hydrogenated amorphous silicon in which an n-type impurity such as phosphorus is doped at a high concentration or silicide. The first ohmic contacts 163a and 165a make a pair to be disposed on the first semiconductor 154a, and the second ohmic contacts 163b and 165b also make a pair to be disposed on the second semiconductor 154b.

A plurality of data conductors including a plurality of data lines 171, a plurality of driving voltage lines 172, and a plurality of first and second output electrodes 175a and 175b is formed on the ohmic contacts 163a, 163b, 165a, and 165b and the gate insulating layer 140.

The data lines 171 transfer data signals and mainly extend in a vertical direction to cross the gate lines 121. Each data line 171 includes a plurality of first input electrodes 173a which extends toward the first control electrode 124a, and a wide end portion 179 for connection with another layer or an external driving circuit. When a data driving circuit (not illustrated) generating a data signal is integrated on the substrate 110, the data line 171 is extended to be directly connected to the data driving circuit.

The driving voltage lines 172 transfer driving voltages and mainly extend in a vertical direction to cross the gate lines 121. Each driving voltage line 172 includes a plurality of second input electrodes 173b which extends toward the second control electrode 124b. The driving voltage line 172 is overlapped with the storage electrode 127 to be connected to the driving voltage line 172.

The first and second output electrodes 175a and 175b are separated from each other and separated from the data line 171 and the driving voltage line 172. The first input electrode 173a and the first output electrode 175a face each other based on the first control electrode 124a, and the second input electrode 173b and the second output electrode 175b face each other based on the second control electrode 124b.

The data conductors 171, 172, 175a, and 175b may be made of refractory metal such as molybdenum, chromium, tantalum, and titanium or an alloy thereof, and may have a multilayered structure including a refractory metal layer (not illustrated) and a low resistive conductive layer (not illustrated). An example of the multilayered structure may include a double layer including a chromium or molybdenum (alloy) lower layer and an aluminum (alloy) upper layer, and a triple layer including a molybdenum (alloy) lower layer, an aluminum (alloy) intermediate layer, and a molybdenum (alloy) upper layer. However, the data conductors 171, 172, 175a, and 175b may be made of various metals or conductors in addition to the metals.

Like the gate conductors 121 and 124b, sides of the data conductors 171, 172, 175a, and 175b are also tilted to the surface of the substrate 110, and tilt angles thereof may be about 30° to about 80°.

The ohmic contacts 163a, 163b, 165a, and 165b exist only between the semiconductors 154a and 154b therebelow and the data conductors 171, 172, 175a, and 175b thereabove, and lower contact resistance. An exposed portion which is not covered by the data conductors 171, 172, 175a, and 175b in addition to a space between the input electrodes 173a and 173b and the output electrodes 175a and 175b is disposed in the semiconductors 154a and 154b.

On the data conductors 171, 172, 175a, and 175b and the exposed portion of the semiconductors 154a and 154b, a passivation layer 180 is formed. The passivation layer 180 is made of an inorganic insulator such as silicon nitride or silicon oxide, an organic insulator, a low-dielectric insulator, and the like. Dielectric constants of the organic insulator and the low-dielectric insulator may be 4.0 or less, and an example of the low-dielectric insulator may include a-Si:C:O, a-Si:O:F, and the like formed by plasma enhanced chemical vapor deposition (PECVD). The passivation layer 180 may be made of an organic insulator having photosensitivity, and the surface of the passivation layer 180 may be flat. However, the passivation layer 180 may have a double-layered structure of a lower inorganic layer and an upper organic layer so as not to damage the exposed portion of the semiconductors 154a and 154b while maintaining an excellent insulating characteristic of the organic layer.

A plurality of contact holes 182, 185a, and 185b exposing the end portion 179 of the data line 171 and the first and second output electrodes 175a and 175b is formed in the passivation layer 180, and a plurality of contact holes 181 and 184 exposing the end portion 129 of the gate line 121 and the second control electrode 124b is formed in the passivation layer 180 and the gate insulating layer 140.

A plurality of pixel electrodes 191, a plurality of connecting members 85, and a plurality of contact assistants 81 and 82 are formed on the passivation layer 180. The plurality of pixel electrodes 191, the plurality of connecting members 85, and the plurality of contact assistants 81 and 82 are made of a transparent conductive material such as ITO or IZO, or reflective metal such as aluminum, silver, or an alloy thereof.

The pixel electrode 191 is physically and electrically connected to the second output electrode 175b through the contact hole 185b, and the connecting members 85 connected to the second control electrode 124b and the first output electrode 175a through the contact holes 184 and 185a.

The contact assistants 81 and 82 are connected with the end portion 129 of the gate line 121 and the end portion 179 of the data line 171 through the contact holes 181 and 182, respectively. The contact assistants 81 and 82 compensate for adhesion between the end portion 129 of the gate line 121 and the end portion 179 of the data line 171 and an external device and protect the end portion 129 of the gate line 121 and the end portion 179 of the data line 171 and the external device.

A partition 361 is formed on the passivation layer 180. The partition 361 defines an opening 365 by surrounding an edge periphery of the pixel electrode 191 like a bank and may be made of an organic insulator or an inorganic insulator. The partition 361 may also be made of a photoresist including a black pigment, and in this case, the partition 361 serves as a light blocking member, and a forming process thereof is simple.

The organic light emitting member 370 is formed in the opening 365 on the pixel electrode 191 defined by the partition 361. The organic light emitting member 370 is made of an organic material which uniquely expresses any one of the primary colors such as three primary colors of red, green and blue. The organic light emitting diode display displays a desired image by spatial combination of the primary colored light expressed by the organic light emitting members 370.

The organic light emitting member 370 may have a multilayered structure including auxiliary layers (not illustrated) for improving light emission efficiency of an emitting layer in addition to the emitting layer (not illustrated) emitting light. In the auxiliary layers, an electron transport layer (not illustrated) and a hole transport layer (not illustrated) for adjusting a balance of electrons and holes, and an electron injecting layer (not illustrated) and a hole injecting layer (not illustrated) for reinforcing injection of the electrons and the holes are included.

A common electrode 270 is formed on the organic light emitting member 370. The common electrode 270 receives a common voltage Vss and may be made of reflective metal including calcium (Ca), barium (Ba), magnesium (Mg), aluminum, silver, and the like, or a transparent conductive material such as ITO or IZO.

In such an organic light emitting diode display, the first control electrode 124a connected to the gate line 121, and the first input electrode 173a and the first output electrode 175a connected to the data line 171 form a switching TFT Qs together with the first semiconductor 154a, and a channel of the switching TFT Qs is formed in the first semiconductor 154a between the first input electrode 173a and the first output electrode 175a. The second control electrode 124b connected to the first output electrode 175a, the second input electrode 173b connected to the driving voltage line 172, and the second output electrode 175b connected to the pixel electrode 191 form a driving TFT Qd together with the second semiconductor 154b, and a channel of the driving TFT Qd is formed in the second semiconductor 154b between the second input electrode 173b and the second output electrode 175b. The pixel electrode 191, the organic light emitting member 370, and the common electrode 270 form the organic light emitting diode LD, and the pixel electrode 191 is an anode and the common electrode 270 is a cathode, or reversely, the pixel electrode 191 is a cathode and the common electrode 270 is an anode. The storage electrode 127 and the driving voltage line 172 which are overlapped with each other may form a storage capacitor Cst.

Such an organic light emitting diode display emits light upward or downward from the substrate 110 to display an image. An opaque pixel electrode 191 and a transparent common electrode 270 are applied to a top emission type organic light emitting diode display which displays an image in an upper direction of the substrate 110, and a transparent pixel electrode 191 and an opaque common electrode 270 are applied to a bottom emission type organic light emitting diode display which displays an image in a lower direction of the substrate 110.

Meanwhile, when the semiconductors 154a and 154b are polysilion, an intrinsic region (not illustrated) facing the control electrodes 124a and 124b and an extrinsic region (not illustrated) positioned at both sides are included. The extrinsic region is electrically connected to the input electrodes 173a and 173b and the output electrodes 175a and 175b, and the ohmic contacts 163a, 163b, 165a, and 165b may be omitted.

Further, the control electrodes 124a and 124b may be disposed on the semiconductors 154a and 154b, and even in this case, the gate insulating layer 140 is positioned between the semiconductors 154a and 154b and the control electrodes 124a and 124b. In this case, the data conductors 171, 172, 173b, and 175b are positioned on the gate insulating layer 140, and may be electrically connected with the semiconductors 154a and 154b through a contact hole (not illustrated) penetrated in the gate insulating layer 140. Unlike this, the data conductors 171, 172, 173b, and 175b are positioned below the semiconductors 154a and 154b to electrically contact the semiconductors 154a and 154b thereon.

### EXAMPLES

### Example 1

An example of measurement of light efficiency of an organic light emitting diode display including an organic film layer with a convex portion according to an embodiment.

In order to measure light efficiency according to an exemplary embodiment, a conventional organic light emitting diode display, i.e., an organic light emitting diode display without the high refractive organic film layer 301 and the low refractive organic film layer 302, and an organic light emitting diode display according to an exemplary embodiment, were compared. The comparison result is illustrated in the following Table 1.

TABLE 1

| Classification | Comparative Example | Exemplary Embodiment |
|---|---|---|
| Side efficiency | 100.0% | 107.2% |
| Total efficiency | 100.0% | 106.9% |

### Example 2

Measurement of light efficiency of an organic light emitting diode display including an organic film layer with a convex portion and a flat portion at a center of the convex portion according to an embodiment.

In order to measure light efficiency according to an exemplary embodiment, a conventional organic light emitting diode display, i.e., an organic light emitting diode display without the high refractive organic film layer 301 and the low refractive organic film layer 302, and an organic light emitting diode display according to an exemplary embodiment, were compared. The comparison result is illustrated in the following Table 2.

TABLE 2

| Classification | Comparative Example | exemplary embodiment |
|---|---|---|
| Side efficiency | 100.0% | 112.5% |
| Total efficiency | 100.0% | 109.1% |

As can be seen in Tables 1 and 2, the organic light emitting diode display according to the exemplary embodiment has excellent light efficiency as compared with the conventional organic light emitting diode display.

As described above, in the organic light emitting diode display according to the exemplary embodiment, high and low refractive organic film lenses are disposed in a thin film structure. As a result, an emission ratio of light, which may be potentially lost due to total reflection of an organic light emitting material, is enhanced without a polarizer to increase light efficiency and to prevent a side color change.

By way of summary and review, in a conventional organic light emitting diode display, a structure for controlling external light reflection without a polarizer and enhancing light efficiency of the organic light emitting layer is used by applying a color filter directly to an upper surface of an encapsulation layer of an organic light emitting panel. However, in such a structure, light loss of the organic light emitting diode display may occur due to a light blocking member, i.e., a black matrix.

In contrast, exemplary embodiments provide an organic light emitting diode display and a method for preparing the same that improve light efficiency by positioning an organic film lens between the color filter and the upper surface of the encapsulation layer of the organic light emitting panel, instead of a polarizer. That is, in the organic light emitting diode display according to the exemplary embodiment, a high refractive organic film layer and a low refractive organic film layer are sequentially formed in a thin film structure, and as a result, an emission ratio of light which may be lost due to total reflection of an organic light emitting material is enhanced without a polarizer to increase light efficiency and prevent a side color change.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. An organic light emitting diode display, comprising:
an organic light emitting panel;
a high refractive organic film layer on the organic light emitting panel, the high refractive organic film layer including a convex portion having a convex shape with respect to the organic light emitting panel;
a low refractive organic film layer on the high refractive organic film, the low refractive organic film layer including a concave portion corresponding to the convex portion of the high refractive organic film layer;
a color filter on the low refractive organic film layer; and
a light blocking member having an opening corresponding to the color filter.

2. The organic light emitting diode display as claimed in claim 1, wherein the organic light emitting panel includes:
a thin film transistor substrate with an organic light emitting layer; and
an encapsulation layer on the thin film transistor substrate.

3. The organic light emitting diode display as claimed in claim 2, wherein a thickness of the encapsulation layer is about 1 μm to about 10 μm.

4. The organic light emitting diode display as claimed in claim 3, wherein the high refractive organic film layer includes one or more of TiOₓ, ZrOₓ and SiNₓ as nano high refractive beada, and the low refractive organic film layer includes a fluorine based material or air nano bead particles.

5. The organic light emitting diode display as claimed in claim 3, wherein an initial formation angle of the convex portion of the high refractive organic film layer and the concave portion of the low refractive organic film layer is about 10° to about 80° according to a size of each pixel.

6. The organic light emitting diode display as claimed in claim 5, wherein heights of the convex portion and the concave portion are in a range of about 1 μm to about 6 μm.

7. The organic light emitting diode display as claimed in claim 5, wherein widths of the convex portion and the concave portion are about (−5) μm to about (+5) μm with respect to a width of each pixel according to widths of the red, green, and blue pixels.

8. The organic light emitting diode display as claimed in claim 5, wherein a combined thickness of the high and low refractive organic film layers is about 5 μm to about 20 μm.

9. The organic light emitting diode display as claimed in claim 5, wherein a refractive index of the high refractive organic film layer has a range of about 1.7 to about 1.9, and a refractive index of the low refractive organic film layer has a range of about 1.2 to about 1.5.

10. The organic light emitting diode display as claimed in claim 5, wherein the high refractive organic film layer and the low refractive organic film layer are configured in a mono lens structure or a multi lens structure.

11. The organic light emitting diode display as claimed in claim 3, wherein a thickness of the light blocking member is about 1 μm to about 5 μm.

12. The organic light emitting diode display as claimed in claim 11, wherein a linear distance between the light blocking member and the organic light emitting layer is about 2 μm to about 6 μm.

13. The organic light emitting diode display as claimed in claim 11, wherein a thickness of the color filter is about 1 μm to about 5 μM.

14. The organic light emitting diode display as claimed in claim 1, further comprising an adhesive layer between the encapsulation layer and the high refractive organic film layer or between the low refractive organic film layer film layer and the color filter.

15. The organic light emitting diode display as claimed in claim 14, wherein a thickness of the adhesive layer is about 5 μm to about 50 μm.

16. The organic light emitting diode display as claimed in claim 1, wherein a center portion of an upper surface of the convex portion of the high refractive organic film layer is flat, and a center portion of a lower surface of the concave portion of the low refractive organic film layer is flat.

17. The organic light emitting diode display as claimed in claim 16, wherein the flat portions are about 50% to about 70% of an entire area of each pixel.

18. A method for preparing an organic light emitting diode display, the method comprising:
forming a light blocking member t a boundary between respective pixels of red, green, and blue pixels of a color filter formed on a substrate;
forming a low refractive organic film layer including a concave portion having a concave pattern between the light blocking members on the color filter with the light blocking member;
adhering a high refractive organic film layer including a convex portion corresponding to the concave portion on the low refractive organic film layer by using an adhesive; and
bonding a thin film transistor substrate including an organic light emitting layer on the high refractive organic film layer.

19. The method for preparing an organic light emitting diode display as claimed in claim 18, wherein the light blocking member is formed to have a height of about 1 μm to about 5 μm.

20. The method for preparing an organic light emitting diode display of claim 18, wherein the adhesive is formed of urethane acrylate resin or 2-hydroxy ethyl acrylate.

21. The method for preparing an organic light emitting diode display as claimed in claim 18, wherein bonding of the thin film transistor substrate includes a UV curing method.
